(19) United States
(12) Patent Application Publication
(10) Pub. No.: US 2010/0033164 A1
(43) Pub. Date: Feb. 11, 2010

(54) TRANSIENT NOISE DETECTION CIRCUIT

(75) Inventors: Ming Dou KER, Hsinchu (TW); Wen Yi CHEN, Taipei City (TW); Hsin Chin JIANG, Bade City (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: TRANSIENT NOISE DETECTION CIRCUIT, Taoyuan (TW)

(21) Appl. No.: 12/188,000

(22) Filed: Aug. 7, 2008

(51) Int. Cl. G01R 19/00

(52) U.S. Cl. 324/102

(57) ABSTRACT

A transient noise detection circuit for detecting a level of a transient noise voltage is disclosed. The transient noise detection circuit comprises a triggering circuit, a rectifying circuit, and a controller. The triggering circuit is coupled between a power rail and a ground node. When the triggering circuit receives a transient noise, the triggering circuit generates a triggering signal. The rectifying circuit comprises a rectifying unit and a current-limiting unit coupled in series. When the rectifying unit receives the triggering signal from the triggering circuit, the rectifying unit will be triggered by the triggering signal. The controller is coupled to a detection node between the rectifying unit and the current-limiting unit. The controller is used for determining the level of the transient noise voltage based on the voltage of the detection node.

### BACKGROUND OF THE INVENTION

1. Field of the invention

The invention relates to transient noise detection. In particular, the invention relates to a transient noise detection circuit.

2. Description of the prior art

As the scale of devices in ICs has become smaller, the devices have become more vulnerable to the fast noise transient event, for example, electrostatic discharge (ESD) or electrical fast transient (EFT). Hence, ESD has been one of the most important reliability issues for IC products and must be taken into consideration in the design phase of all ICs.

Besides the unit-level ESD issue, the system-level ESD issue is also an increasingly significant reliability issue in CMOS IC products. It has known that some CMOS ICs are very susceptible to system-level ESD stress, even though they have passed the unit-level ESD specifications such as human-body-model (HBM) of ±2 kV, machine-model (MM) of ±200V, and charged-device-model (CDM) of ±1 kV.

In system-level ESD tests, a normal power is provided to the internal circuits of an IC and the internal circuits are operated to perform their default functions. The purpose of system-level ESD tests is to determine whether the internal circuits can keep normal operations even being interfered by ESD noises or whether the circuits can be automatically reset to recover themselves. In the system-level ESD test standard, IEC 61000-4-2, electronic products must sustain the ESD level of +8 kV under contact-discharge test and +15 kV under air-discharge test to meet the immunity requirement of “level 4”. High-energy ESD-induced noises often cause damage or malfunction of CMOS ICs inside the equipment under test (EUT).

FIG. 1 shows the connecting relationship of a system-level ESD detection circuit 16 and an internal circuit 14 in an IC chip. Under the normal power-on condition, a power-on/reset circuit 12 starts up the internal circuit 14 and resets the ESD detection circuit 16. Thereafter, the internal circuit 14 starts its default operations and the ESD detection circuit 16 starts to detect ESD events. Once a sudden voltage overshoot or undershoot happens on the power rail (V_{DD} or V_{SS}), the ESD detection circuit 16 will inform the power-on/reset circuit 12 to perform a protection procedure for the internal circuit 14.

In practical applications, the different protection procedures may be used in different ICs with various firmware or circuit designs. For instance, the power-on/reset circuit 12 might reset the whole or only one part of the internal circuit 14. By doing so, more serious malfunction of the whole chip may be accordingly prevented.

A system-level ESD detection circuit has been proposed in “On-chip transient detection circuit for system-level ESD protection in CMOS integrated circuits to meet electromagnetic compatibility regulation” reported by M.-D. Ker, C.-C. Yen, and P.-C. Shih on IEEE Trans. Electromagnetic Compatibility, vol. 50, no. 1, pp. 1-9, February 2008. Please refer to FIG. 2. FIG. 2 shows the ESD detection circuit in the above-mentioned paper.

As shown in FIG. 2, the capacitors C_{P1} and C_{P2} are respectively used for detecting fast transients happened on V_{DD} and V_{SS} when the system is subjected to ESD events. As a result, the circuit in FIG. 2 can detect the system level ESD noise and send an output signal to convey the event of ESD transition to power-on reset/internal circuit. After the internal circuit has dealt with the ESD transient noise, the detection circuit can be reset again.

In the prior art, it can be seen that the detection circuit uses the passive devices (capacitors Cₚ₁ and Cₚ₂) to couple the system-level ESD transient noise. However, this technique to couple ESD transient noise through passive devices can be severely affected by parasitic loadings on the system, for example, the parasitic capacitance of the connectors onboard.

### SUMMARY OF THE INVENTION

To solve the aforementioned problem, a scope of the invention is to provide transient noise detection circuits capable of judging the level of transient noise voltages.

An embodiment according to the invention is an ESD detection circuit. The ESD detection circuit is used for detecting a level of an ESD voltage. The ESD detection circuit comprises a triggering circuit, a rectifying circuit, and a controller.

The triggering circuit is coupled between a power rail and a ground node. When the triggering circuit receives a transient noise, the triggering circuit generates a triggering signal. The rectifying circuit is coupled to the triggering circuit, the power rail, and the ground node. The rectifying circuit comprises a rectifying unit and a current-limiting unit coupled in series.

In practical applications, the rectifying unit can comprise a silicon-controlled rectifier (SCR) device and the current-limiting unit can comprise at least one MOSFET (Metal-Oxide-Semiconductor Field Effect Transistor) device.

When the rectifying unit receives the triggering signal from the triggering circuit, the rectifying unit is triggered by the triggering signal. The controller is coupled to a detection node between the rectifying unit and the current-limiting unit. The controller is used for determining the level of the ESD voltage based on the voltage of the detection node.

Compared to the prior arts, the transient noise detection circuit according to the invention combines a SCR device and a current-limiting MOSFET device, instead of the passive devices in prior art, to detect fast noise transient events. Therefore, the transient noise detection circuit according to the invention can prevent being affected by parasitic loadings on the system.

In addition, since the transient noise detection circuit can detect the level of an ESD voltage, the subsequent circuit can perform a corresponding measure to provide a flexible ESD protection policy. Further, because the structure and units therein are quite simple, the transient noise detection circuit according to the invention can be implemented easily.

The advantage and spirit of the invention may be understood by the following recitations together with the appended drawings.

### BRIEF DESCRIPTION OF THE APPENDED DRAWINGS

FIG. 1 shows the connecting relationship of a system level ESD detection circuit and an internal circuit in an IC chip in the prior art.

FIG. 2 shows an example of the ESD detection circuit in the prior art.

FIG. 3(A) shows the basic structure of the ESD detection circuit in the first embodiment according to the invention.

FIG. 3(B) shows the basic structure of the ESD detection circuit in the second embodiment according to the invention.

FIG. 4(A) shows the detailed diagram of the ESD detection circuit in FIG. 3(A).

FIG. 4(B) shows the detailed diagram of the ESD detection circuit in FIG. 3(B).

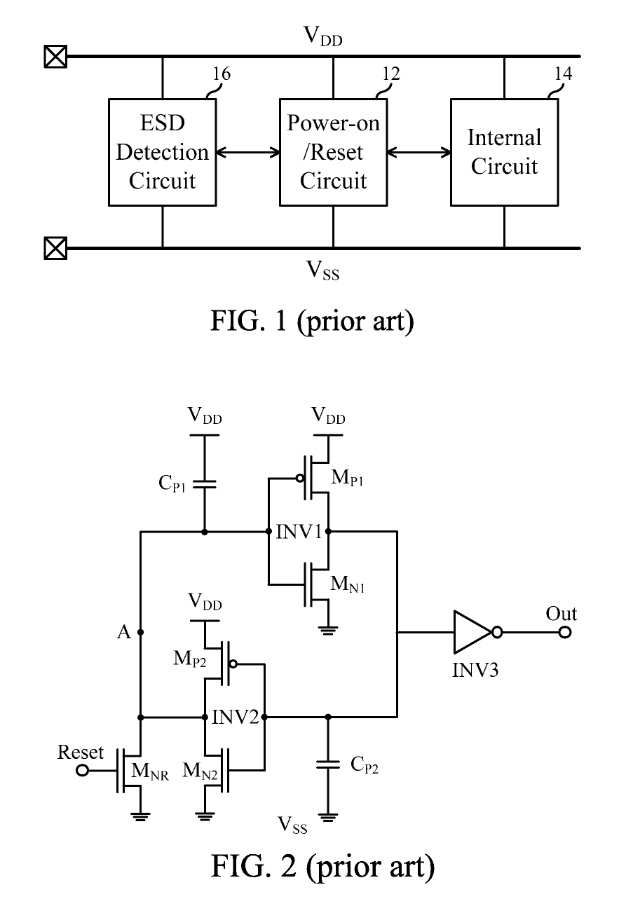

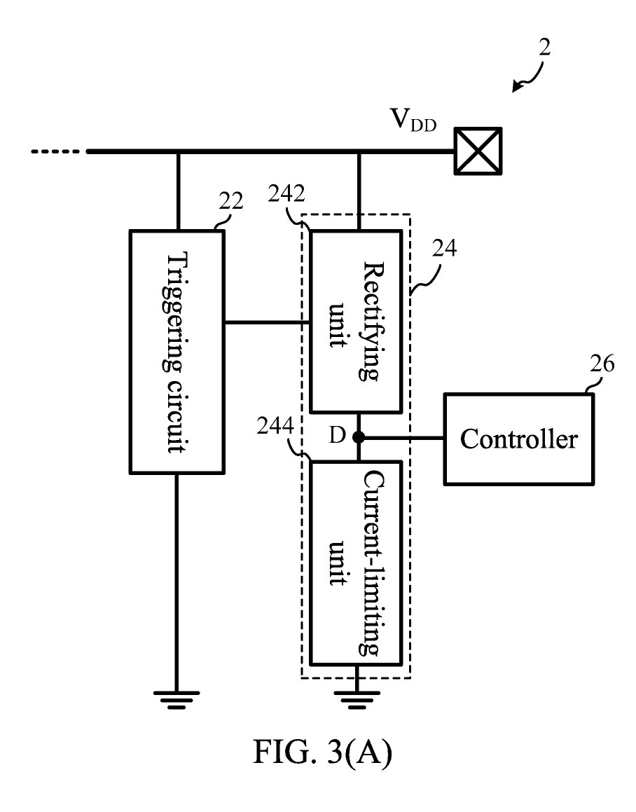

### DETAILED DESCRIPTION OF THE INVENTION

The invention provides a transient noise detection circuit capable of judging the level of a transient noise voltage. In fact, sources of the transient noise voltage can be like ESD voltage or EFT voltage.

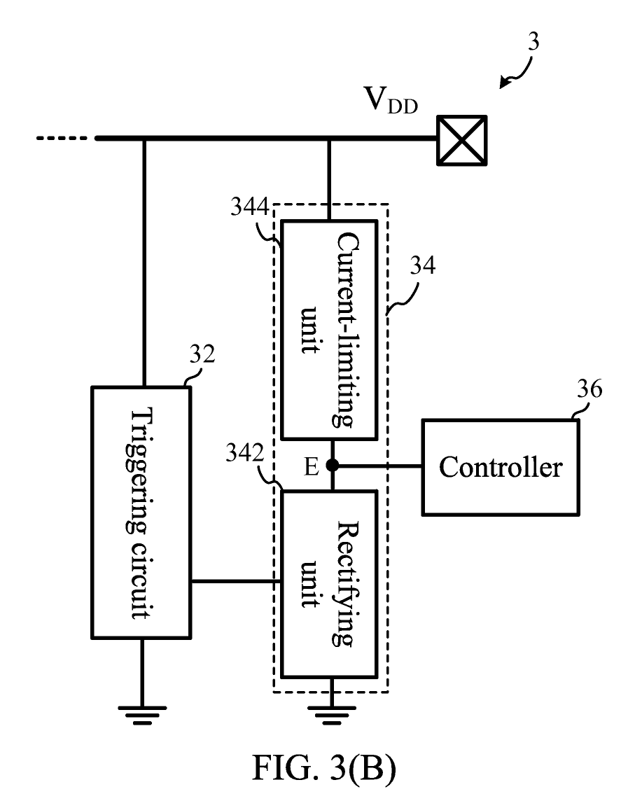

A first embodiment according to the invention is an ESD detection circuit. Please refer to FIG. 3(A). FIG. 3(A) shows a basic structure of the ESD detection circuit in the first embodiment according to the invention. As shown in FIG. 3(A), the ESD detection circuit 2 comprises a triggering circuit 22, a rectifying circuit 24, and a controller 26. The rectifying circuit 24 comprises a rectifying unit 242 and a current-limiting unit 244. And, the rectifying unit 242 and the current-limiting unit 244 are coupled in series.

In practical applications, the rectifying unit 242 can comprise a silicon-controlled rectifier (SCR) device and the current-limiting unit 244 can comprise at least one MOSFET (Metal-Oxide-Semiconductor Field Effect Transistor) device. For example, the current-limiting unit 244 can be a NMOS stack comprising three NMOS coupled in series.

The triggering circuit 22 is coupled between a power rail (V_{DD}) and a ground node. When the triggering circuit 22 receives a transient noise, the triggering circuit 22 generates a triggering signal. In fact, the triggering circuit 22 can be used to trigger the rectifying unit 242, such as the SCR device. And, the triggering circuit 22 can comprise a resistor, a capacitor, and an inverter. In addition, the triggering circuit 22 can also comprise a resistor, a capacitor, and an inverter chain comprising a plurality of inverters coupled in series.

As shown in FIG. 3(A), the rectifying unit 242 of the rectifying circuit 24 is coupled to the triggering circuit 22 and the power rail. When the rectifying unit 242 receives the triggering signal from the triggering circuit 22, the rectifying unit 242 is triggered by the triggering signal. In addition, the current-limiting unit 244 of the rectifying circuit 24 is coupled to the rectifying unit 242 and the ground node. The current-limiting unit 244 can control the overall power consumption of the proposed detection circuit.

As shown in FIG. 3(A), the controller 26 is coupled to a detection node D. The detection node D is a node between the rectifying unit 242 and the current-limiting unit 244. The controller 26 detects a voltage of the detection node D and then determines the level of the ESD voltage based on the voltage of the detection node D.

In practical applications, if the level of the ESD voltage that the controller 26 determines is abnormally high, the controller 26 can immediately reboot or restart the internal circuit for higher electromagnetic compatibility (EMC) robustness of system apparatus. Therefore, the ESD detection circuit 2 according to the invention can provide the function of noise detection for system apparatus.

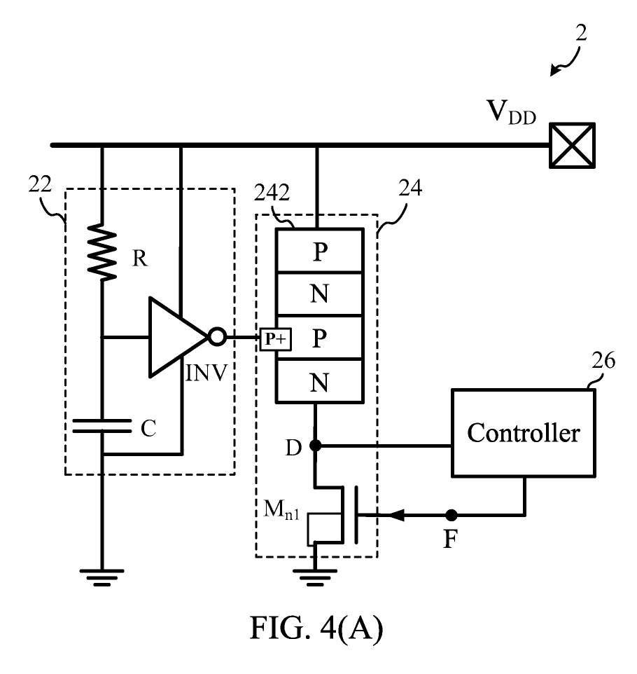

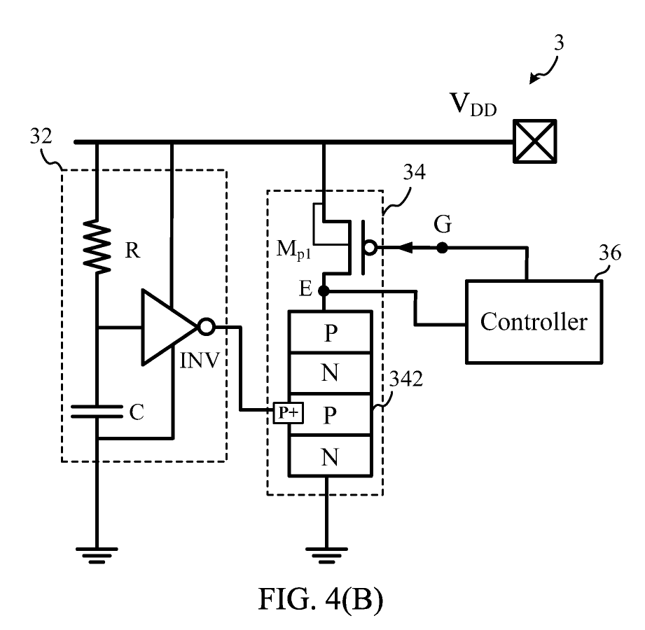

Please refer to FIG. 4(A). FIG. 4(A) shows a detailed diagram of the ESD detection circuit shown in FIG. 3(A). As shown in FIG. 4(A), the triggering circuit 22 comprises an inverter INV and a RC unit comprising a resistor R and a capacitor C coupled in series. The RC unit is coupled to the power rail and the ground node. The inverter INV is coupled to the power rail, the ground node, the rectifying unit 242, and a node between the resistor R and the capacitor C. If the RC unit receives the transient noise from the power rail, the RC unit will generate a RC delay signal. Then, the inverter INV will receive the RC delay signal from the RC unit and generate the triggering signal according to the RC delay signal.

In practical applications, the triggering circuit 22 can comprise an inverter chain and a RC unit. For example, the inverter chain can comprise four inverters coupled in series and the RC unit can comprise a resistor R and a capacitor C coupled in series. In fact, the structure of the triggering circuit 22 is not limited by this embodiment. It has still other possible structures for the triggering circuit 22.

As shown in FIG. 4(A), the rectifying unit 242 of rectifying circuit 24 is a SCR device and the current-limiting unit 244 is a NMOS device Mₙ₁. The SCR device 242 is coupled to the inverter INV of the triggering circuit 22 and the power rail. The NMOS device Mₙ₁ and the rectifying unit 242 are connected in series, and the NMOS device Mₙ₁ is also coupled to the ground node. After the triggering signal is generated by the inverter INV, the SCR device 242 will receive the triggering signal from the inverter INV. Then, the SCR device 242 will be triggered by the triggering signal.

Then, the controller 26 shown in FIG. 4(A) will be discussed. As shown in FIG. 4(A), the controller 26 is coupled to a detection node D and a gate terminal of the NMOS device Mₙ₁. The detection node D is a node between the SCR device 242 and the NMOS device Mₙ₁. The controller 26 is used for detecting a voltage of the detection node D and then determining the level of the ESD voltage based on the voltage of the detection node D.

In addition, in order to reset the ESD detection circuit 2, the controller 26 will generate a reset signal and transmit the reset signal through a reset node F to the gate terminal of the NMOS device Mₙ₁. Then, the NMOS device Mₙ₁ will be turned off and the current flowing through the SCR device 242 will drop below its holding current (Iₕ). So, the SCR device 242 will be turned-off due to the insufficient holding current (Iₕ). As a result, the ESD detection circuit 2 is reset and ready to detect another transient noise event.

In practical applications, the controller 26 can further connect to a subsequent circuit and the subsequent circuit can receive the level of the ESD voltage from the controller 26. Based on the level of the ESD voltage, the subsequent circuit can perform a corresponding measure and provide a flexible ESD protection policy.

A second embodiment according to the invention is also an ESD detection circuit. Please refer to FIG. 3(B). FIG. 3(B) shows a basic structure of the ESD detection circuit in the second embodiment according to the invention. As shown in FIG. 3(B), the ESD detection circuit 3 comprises a triggering circuit 32, a rectifying circuit 34, and a controller 36. The rectifying circuit 34 comprises a rectifying unit 342 and a current-limiting unit 344. And, the rectifying unit 342 and the current-limiting unit 344 are coupled in series.

In practical applications, the rectifying unit 342 can comprise a SCR device and the current-limiting unit 344 can comprise at least one MOSFET device. For example, the current-limiting unit 344 can be a PMOS stack comprising four PMOS coupled in series.

It should be noticed that the rectifying unit 342 is coupled to the triggering circuit 32 and a ground node, and the current-limiting unit 344 is coupled to a power rail (V_{DD}) and the rectifying unit 342. The controller 36 is coupled to a detection node E. The detection node E is a node between the rectifying unit 342 and the current-limiting unit 344. The controller 36 detects a voltage of the detection node E and then determines the level of the ESD voltage based on the voltage of the detection node E.

Please refer to FIG. 4(B). FIG. 4(B) shows a detailed diagram of the ESD detection circuit in FIG. 3(B). As shown in FIG. 4(B), the triggering circuit 32 comprises an inverter INV and a RC unit comprising a resistor R and a capacitor C coupled in series. The RC unit is coupled to the power rail and the ground node. The inverter INV is coupled to the power rail, the ground node, the rectifying unit 242, and a node between the resistor R and the capacitor C. If the RC unit receives the transient noise from the power rail, the RC unit will generate a RC delay signal. Then, the inverter INV will receive the RC delay signal from the RC unit and generate the triggering signal according to the RC delay signal.

In practical applications, the triggering circuit 32 can comprise an inverter chain and a RC unit. For example, the inverter chain can comprise five inverters coupled in series and the RC unit can comprise a resistor R and a capacitor C coupled in series.

As shown in FIG. 4(B), the rectifying unit 342 of rectifying circuit 34 is a SCR device and the current-limiting unit 344 is a PMOS device Mₚ₁. The SCR device 342 is coupled to the inverter INV of the triggering circuit 32 and the ground node. The PMOS device Mₚ₁ and the rectifying unit 342 are connected in series, and the PMOS device Mₚ₁ is also coupled to the power rail. After the triggering signal is generated by the inverter INV, the SCR device 342 will receive the triggering signal from the inverter INV. Then, the SCR device 342 will be triggered by the triggering signal.

As shown in FIG. 4(B), the controller 36 is coupled to a detection node E and a gate terminal of the PMOS device Mₚ₁. The detection node E is a node between the SCR device 342 and the PMOS device Mₚ₁. In this embodiment, the controller 36 is used for detecting a voltage of the detection node E and then determining the level of the ESD voltage based on the voltage of the detection node E.

In practical applications, if the level of the ESD voltage that the controller 36 determines is abnormal, the controller 36 can immediately reboot or restart the internal circuit for higher EMC robustness of system apparatus. Therefore, the ESD detection circuit 3 according to the invention can provide the function of noise detection for system apparatus.

To sum up, the transient noise detection circuit according to the invention can combine a SCR device and a current-limiting MOSFET device, instead of the passive devices in prior art, to detect fast noise transient events. Therefore, the transient noise detection circuit can prevent being affected by parasitic loadings on the system.

In addition, the transient noise detection circuits according to the invention can detect not only the occurrence of ESD events but also the level of an ESD voltage. Based on the level of an ESD voltage, the subsequent circuit can perform a corresponding measure and a flexible ESD protection policy can be provided. Further, because the structure and units therein are quite simple, the transient noise detection circuits according to the invention can be implemented easily.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A transient noise detection circuit for detecting a level of a transient noise voltage, comprising:
a triggering circuit coupled between a power rail and a ground node, when the triggering circuit receives a transient noise, the triggering circuit generating a triggering signal;
a rectifying circuit coupled to the triggering circuit, the power rail, and the ground node, comprising a rectifying unit and a current-limiting unit coupled in series, when the rectifying unit receives the triggering signal from the triggering circuit, the rectifying unit being triggered by the triggering signal; and
a controller coupled to a detection node between the rectifying unit and the current-limiting unit, the controller determining the level of the transient noise voltage based on the voltage of the detection node.

2. The transient noise detection circuit of claim 1, wherein the rectifying unit is a silicon-controlled rectifier (SCR).

3. The transient noise detection circuit of claim 1, wherein the current-limiting unit is a PMOS, the PMOS is coupled between the power rail and the rectifying unit, and the rectifying unit is coupled to the ground node.

4. The transient noise detection circuit of claim 1, wherein the current-limiting unit is a PMOS stack, the PMOS stack is coupled between the power rail and the rectifying unit, and the rectifying unit is coupled to the ground node.

5. The transient noise detection circuit of claim 1, wherein the current-limiting unit is a NMOS, the NMOS is coupled between the ground node and the rectifying unit, and the rectifying unit is coupled to the power rail.

6. The transient noise detection circuit of claim 1, wherein the current-limiting unit is a NMOS stack, the NMOS stack is coupled between the ground node and the rectifying unit, and the rectifying unit is coupled to the power rail.

7. The transient noise detection circuit of claim 1, wherein the triggering circuit comprises:
a RC unit coupled to the power rail and the ground node, comprising a resistor and a capacitor coupled in series; and
an inverter coupled to the power rail, the ground node, the rectifying unit, and the RC unit;
wherein when the RC unit receives the transient noise, the RC unit generates a RC delay signal, then the inverter generates the triggering signal according to the RC delay signal.

8. The transient noise detection circuit of claim 1, wherein the triggering circuit comprises:
a RC unit coupled to the power rail and the ground node, comprising a resistor and a capacitor coupled in series; and
an inverter chain coupled to the power rail, the ground node, the rectifying unit, and the RC unit;
wherein when the RC unit receives the transient noise, the RC unit generates a RC delay signal, then the inverter generates the triggering signal according to the RC delay signal.
